(19) United States
(12) Patent Application Publication
(10) Pub. No.: US 2026/0227691 A1
(43) Pub. Date: Aug. 6, 2026

(54) A METHOD AND COMPUTING MEANS OF ANALYSING DATA FROM A RELIEF PLATE PRODUCTION SYSTEM

(71) Applicant: XSYS PREPRESS NV, IEPER (BE)

(72) Inventor: Johan VERVAECKE, IEPER (BE)

(73) Assignee: XSYS PREPRESS NV, IEPER (BE)

(21) Appl. No.: 19/154,127

(22) PCT Filed: Feb. 13, 2024
(86) PCT No.: PCT/EP2024/053640

§ 371 Date: Aug. 6, 2025

(30) Foreign Application Priority Data
Feb. 16, 2023 (NL) 2034160

(51) Int. Cl. G03F 7/00

(52) U.S. Cl. CPC G03F 7/0012

(57) ABSTRACT

A method of analysing data from a relief plate production system comprising at least one, preferably at least two production units for treating a relief plate precursor to obtain a relief plate, and a computing means, the method comprising at said computing means the steps of receiving from the at least one production unit data comprising a plate identifier of the relief plate and information relative to the treatment performed on the relief plate precursor by the respective production unit; analysing the received data and creating a relief plate report based on the analysed data.

### REFERENCE TO RELATED APPLICATIONS

The present application relates to and claims priority of the Dutch patent application 2034160, filed on Feb. 16, 2023, which is hereby explicitly incorporated herein by reference in its entirety.

### FIELD OF THE INVENTION

The field of the invention relates to treating data in a relief plate production system. Embodiments relate to a method and computing means of analysing data from a relief plate production system. Other embodiments relate to a method and computing means of operating a relief plate production system.

### DESCRIPTION OF RELATED ART

Using a relief plate for printing comprises at least two separate steps: first, the relief plate is manufactured. Then ink is applied to the relief plate, and the relief plate transfers ink onto a printing medium. When the printing results using a relief plate are not optimal, there can be at least two sources of the problem. The first potential source is a faulty printing plate itself, i.e., a printing plate that was not manufactured correctly. Another potential source can be that while the relief plate complies with its design specification, there are problems with the printing process such as with the quality of the ink applied to the relief plate or with the transfer process of ink to the printing medium. When the final printing result is not ideal it is however not easy to derive the exact source of the problem. It could be that, when the real problem lies in ink or the printing medium, a technician focusses instead wrongly on the relief plate which turns out to have been manufactured according to the requirements. Also, the source of the problem could be caused by a manufacturing step, such as an imaging step or an exposure step or a development step which has not been performed as required, and it may be difficult to derive from where the problem originates.

### SUMMARY OF THE INVENTION

The object of embodiments of the present disclosure is to allow identifying the source of the problem when the printing result using a relief plate is not meeting the required quality or when the relief plate shows other deficiencies. In particular, the object of some embodiments of the present disclosure is to allow deriving whether the cause of the problem is associated with a particular manufacturing step or whether the manufactured relief plate fulfils the required standards and the issue originated from the printing process.

According to a first aspect there is provided a method of analysing data from a relief plate production system comprising at least one, preferably at least two production units for treating a relief plate precursor to obtain a relief plate and a computing means. The method comprises at said computing means the steps of receiving from the at least one production unit data. The data comprises a plate identifier of the relief plate and information relative to the treatment performed on the relief plate by the respective production unit. The method also comprises at said computing means the step of analysing the received data and creating a relief plate report based on the analysed data.

Thanks to these features the relief plate report contains detailed information about the results of the different manufacturing steps performed by the at least one, preferably at least two production units, allowing to derive a cause of a problem during the manufacturing process. Also, when the relief plate report indicates a correct manufacturing, it may be derived that the problem is rather related with the printing process. Thus, when a problem in the final printing result occurs, using the relief plate report it can be estimated where the problem came from: does it come from the relief printing plate itself, or the specification of the relief printing plate is according to the requirement and the problem has its origin in the actual printing. In this way, it is easier to identify the source of problems in the printing result.

In addition, the relief plate reports can serve as a quality certificate from the printing plate manufacturer. When a printing problem occurs the printing plate producer can analyse the relief plate report and confirm that a relief plate has been produced according to the specification from the client. In this way they can be certain that any problem in the printing result is not due to a faulty relief plate but should be attributed instead to some other reasons such as ink or the printing medium or how ink was transferred to the printing medium in the printing machine.

Further, the analysis of the data may be carried out by a computing means, preferably separate from the at least one production unit. Often the production units do not have sufficient computational power to analyse the data quickly enough. Sending the data over to the computing means can accelerate the data analysis.

Preferably, the relief plate report comprises aggregated information on the treated relief plate precursor based on the information received from the at least one production unit. The aggregated information provides an overview of any relevant processing information of the various manufacturing steps performed to obtain the relief plate. This is advantageous when one wants to have a global view of the treatments performed the relief plate precursor and allows to better identify the cause of a problem during manufacturing.

The relief plate report may comprise any one or more of the following: the plate identifier of the relief plate, dimensions of the relief plate, such as a length, width and thickness of the relief plate, identifiers of the at least one production unit that has treated the relief plate precursor, settings used in the at least one production unit, a waste percentage indicating an area of a relief plate not taken up by image files compared to the total area of the relief plate, a job identifier identifying a job performed on the relief plate precursor by the at least one production unit, image data associated with the treatment by the at least one production unit, measurement data measured during or after the treatment by the at least one production unit, such as a floor thickness or relief depth, a warning if an anomaly is detected in the analysed data.

Thus, the relief plate report may not only contain information that allows to derive a cause of a problem but may also comprise information that is useful to have for the manufacturer and/or for the client performing printing with the manufactured relief plate. For example, such plate reports may be used to generate statistical data and may be helpful in improving the manufacturing process.

Preferably, the computing device sends the created relief plate report to an external terminal, such as a user device, e.g. a smartphone or other computer device. In this way an operator of the plate production system or customer performing printing can easily consult the relief plate reports.

In a preferred embodiment, the received data comprises measurement data based on measurements performed by the at least one production unit and/or the method further comprises receiving measurement data from a separate unit downstream of the at least one production unit. In this way the impact of a treatment by a production unit on the relief plate precursor may be measured, and such measurement may be used to evaluate the results of the manufacturing. For example, the floor thickness may be measured after development of a relief plate precursor, or a stain level or a relief depth of the treated plate may be measured. It is noted that the separate unit may be for example a unit located at the premisses where the relief plate is manufactured or a unit located at the premisses of a client performing printing with the relief plate.

According to some embodiments the method comprises the receiving of other data by the computing means after the relief plate production system has produced a relief plate and/or during the production. The data is for instance uploaded by an operator. The data may be for instance information related to the printing result obtained with this produced relief plate, information related to environmental conditions during the production (e.g. environment temperature), information relating to a malfunctioning component of a production unit, measurement data performed on the plate by a user using a measurement tool, etc.

Preferably, the measurement data comprises data about a physical property of a treated relief plate precursor, such as a plate thickness, and/or a thickness of a floor of the treated relief plate precursor, and/or measurement data based on a measured printing result such as a lowest stable tonal value produced in the relief plate, and/or a dot gain. The lowest stable tonal value for example is determined through a visual inspection using a microscope on a printed test image which contains fields with different tonal values. The dot gain is for example determined by using a colour densitometer on a printed test image. With these measurement data the relief plate report can provide an accurate indication of the results of the treatments performed on the relief plate precursor, which may help in pinpointing the source of any potential problem on the relief plate.

Additional measurement data concerning the properties of a relief precursor or relief are selected from the group of: thickness of the precursor, thickness of the finished plate, thickness of the floor, depth of the relief, minimum tonal value, tonal value curve, dot gain curve, isolated dot sizes, depth of negative lines, width of positive lines, straightness of lines, depth of negative dots, shape of dots, shoulder angle, roundness of dots (evaluated on a range from round tops to flat tops), intermediate depth of tonal value fields, hardness, surface energy of floor and/or printing features (e.g. using contact angle measurement), elasticity, elastic modulus, curling tendency, anisotropy, roughness, resilience, or combinations thereof.

Optionally, the measurement data comprises production unit related data and/or data related to the environment around a production unit, such as a temperature of the relief plate precursor before and/or during and/or after the treatment, and/or a temperature inside at least one production unit. Such production unit and/or environmental data may further help in analysing and optimising the relief plate manufacturing process. For example, when the quality of the printing results is reduced or increased without having changed the manufacturing process, such parameters may help in understanding where the manufacturing process should be adjusted or better controlled.

Optionally, the measurement data comprises data based on results of printing with the treated plate, optionally further including printing related data such as type of ink, type of printing medium. For example, a client performing the printing process may provide feedback on the quality of the printing results obtained with a certain type of ink and printing medium, and this may be further included in the relief plate report. By including also the results of printing with the relief plate, not only information about what happened during the manufacturing of the plate, but also printing information for a determined printing process specifying e.g. the ink, the printing medium and any other relevant printing parameters (e.g. printing speed, printing pressure, run length), may be included in the relief plate report. Consequently, one could derive more directly whether any potential issue came from the manufacturing of the relief plate itself or rather from a step in the printing process.

Preferably, the at least one production unit comprises an imager configured to ablate a mask for a subsequent exposure step with an imaging means, such as a laser, and the relief plate report comprises one or more of the following: an imaging duration, imaging power, imaging speed, positions of the imaging means, measured parameters of an actuator such as a motor used for moving the imaging means relative to the relief plate precursor, such as motor current, motor speed, a time interval used for generating an imaged feature corresponding with an imaging pixel, e.g. an on-time value for controlling a beam of the imaging means, a beam diameter value and/or beam shape value for controlling a beam of the imaging means, a number of passes performed by the imaging means, an indication of which one or more imaging heads of the imaging means have been used, temperature inside the imager, power consumed by the imager. Optionally the imager may comprise means to investigate the quality of the obtained mask e.g. by determination of the optical density or other optical methods, such as those described in DE 20 2022 002301 U1 and US 2022/0349796 A1. In addition, time of operation (such as start time, end time, or the duration) of the different components may be recorded. Such parameters may not only allow to improve the manufacturing process but also to determine when a component of the imager is not working properly.

Preferably, the at least one production unit comprises an exposure unit with a main and/or back exposure means for exposing a relief side and a back side of the relief plate precursor, and the relief plate report comprises one or more of the following: main and/or back exposure time, main and/or back exposure power and/or dose, number of exposure cycles performed by the main and/or back exposure means, a speed at which the main and/or back exposure means is moved relative to the relief plate precursor, temperature of the relief plate precursor and/or a temperature in the exposure unit, data related to cooling of the exposure unit, power consumed by the exposure unit. By including also temperature and/or cooling related data which is important for a good exposure result, in the plate relief report, a problem with the exposure can be identified in an improved manner. In addition, time of operation of the different components may be recorded.

Preferably, the at least one production unit comprises a washer, and the relief plate report comprises one or more of the following: nature of the washing medium (e.g. solvent or water), washing speed, washing temperature, washing duration, viscosity data of a liquid in the washer, a solid content of the liquid, levels of the liquids in different compartments of the washer, consumption of liquid, time of addition or removal of liquid, power consumed by the washer.

Preferably, the at least one production unit comprises a dryer, and the relief plate report comprises one or more of the following: drying temperature, drying duration, consumption of a drying medium (e.g. air), power consumed by the dryer.

Preferably, the at least one production unit comprises a post-exposure unit, and the relief plate report comprises one or more of the following: the type of light source (e.g. UVA, UVC), the duration of exposure, the power of exposure, the temperature during exposure, power consumed by the exposure unit. In addition, time of operation of the different components of the post-exposure unit may be recorded.

The relief plate report may comprise one or more of data concerning the processing of a relief precursor such as one or more of the following: the date of processing, the total processing time, resting times between different treatment steps, sequence of treatment steps, interruptions, errors, manual handling steps.

The method may comprise the step of analysing the relief plate report when a parameter or a printing result of the relief plate does not fall within its expected range or printing quality and determining a cause thereof. Those additional steps may also be performed by the computing means. Predetermined criteria may be developed to derive from the information in the relief plate report, whether there is a problem and what a possible cause for the problem is.

The method may further comprise in a production unit, the step of reading or receiving the plate identifier of a relief plate precursor that is to be treated, and sending the plate identifier together with the information relative to the treatment performed to the computing means. Optionally, also a job identifier identifying a job performed on the relief plate may be received by the production unit and sent to the computing means.

The method further comprises the step of attaching or including the relief plate report or an identifier of the relief plate report to/with the relief plate. This feature links a relief plate report to a specific treated relief plate. The relief plate report thus acts as a passport of the treated relief plate which accompanies the latter, for example when the treated relief plate is sold to a customer. The manufacturer of the relief plate and/or the customer printing with the relief plate can identify with the help of the relief plate report whether a problem came from the relief plate itself or from a later printing process where ink is applied to the relief plate.

According to another aspect there is provided a method of analysing data from a relief plate production system comprising at least one, preferably at least two production units for treating a relief plate precursor to obtain a relief plate and a computing means. The method comprises at said computing means the steps of receiving from the at least one production unit data. The data comprises information relative to the treatment performed on the relief plate by the respective production unit, and optionally a plate identifier of the relief plate and/or information relative to a status of the respective production unit. More generally the received data may be any of the data detailed above for the first aspect. The method also comprises at said computing means the step of analysing the received data and creating a status report of the relief plate production system. The status report gives an overview of the production status of the relief plate production system and is generated by the computing means based on the received and analysed data over a period of time. The status report is for example provided periodically, such as on a daily, weekly, or monthly basis. The status report is for example sent to an operator periodically, such as sent out via an email. In this way, compared to providing information on a display of the relief plate production system, an operator receives automatically an overview of the status of the relief plate production system.

According to a further aspect there is provided a method of analysing data from one or more relief plate production systems each comprising at least one, preferably at least two production units for treating a relief plate precursor and obtaining a relief plate and a computing means. The method comprises at said computing means the steps of receiving from each production unit of the one or more plate production systems data related to the treatment performed by the respective production unit; and analysing the received data and based thereon showing data in a graphical user interface for a respective plate production system. The graphical user interface is configured to show at least one of the following:
a graphical representation of at least one parameter associated with the respective plate production system in function of time;
a graphical representation of at least one parameter associated with the respective plate production system in function of a resolution of an imaging file used by the respective plate production system;
a graphical representation indicating for each production unit at least one parameter of the respective plate production system;
a graphical representation of at least one parameter associated with power consumption of at least one production unit;
a graphical representation of at least one parameter associated with solvent consumption of at least one production unit;
information allowing a comparison of the respective plate production system with other plate production systems;
a geographical map indicating the one or more plate production system together with one or more parameters associated with said one or more plate production systems.

Thanks to these features it may be possible to follow the temporary evolution of the plate production system. In addition or alternatively, it may be possible to study how the plate production system reacts when image files of different resolutions are input in the plate production system. In addition or alternatively, it is possible to compare parameters from different production units. In addition or alternatively, one could observe the geographical distribution of the plate production systems, and correlate the tendencies observed from the graphical representations to where the production systems are. In addition or alternatively, where there are at least two plate production systems, one could compare one plate production system with the others. For example, some plate production systems may belong to one customer and some other production systems may belong to another customer. With these features one could compare data from various customers and spot trends from the data. In addition, with the graphical user interface information is presented in a more visual way compared to numbers or tables. Data can thus be analysed by an operator in a more straightforward way.

Each plate production system may comprise a production unit of a first type, and the method may further comprise determining based on the received data which features of the production unit of the first type are used for each plate production system, and optionally ranking used features based on a number of times a feature has been used. For one relief plate sometimes not all the features of a production unit are used to treat it. By knowing exactly which features of a production unit are used, the properties of a relief plate can be mapped to the specific features of the production unit more precisely. Also, feedback can be given to the manufacturer of the production units about the features that are being used most.

Preferably, the at least one parameter comprises at least one of the followings: a number of the relief plates treated by a production unit, a surface area treated by a production unit, a waste percentage indicating the area of a relief plate not taken up by image files compared to the total area of the relief plate, a process parameter of a production unit, an integrity parameter of a production unit, power consumption of a production unit, a status of a production unit. A number of plates or a surface area treated in function of time may give a good indication of the efficiency of the production unit. Also, by comparing these number for different production units, the entire plate production system may be rendered more efficient, e.g. by adding a production unit of a type which is slower. Information about the waste percentage may be used to optimize the arranging of images on the relief plate precursor. The status of a production unit will typically be plotted in function of time and may refer to the production unit being “idle”, “producing”, “number of jobs scheduled”, “initializing”, “off”, “error state”, “plate transport mode”, etc. In this way an operator can follow the status of each production unit.

Optionally, the at least one production unit comprises an imager configured to ablate a mask for a subsequent exposure step, and the at least one parameter comprises one or more of the following: a status of the imager, the number of laser beams, the size of laser beams, power consumed by the imager, maximum ablation power of the imager, a ratio of ablation power actually used by the imager for imaging the relief plate compared to the maximum ablation power available on the imager, a measured rotation speed of a drum in the imager with the relief plate precursor being fixed on the drum, a connection quality of the imager, a temperature of the imager and/or of the relief plate precursor, an imaging resolution, an imaging duration, a start time of imaging, an end time of imaging. Optionally the imager may comprise means to investigate the quality of the obtained mask e.g. by determination of the optical density or other optical methods, such as those described in DE 20 2022 002301 U1 and US 2022/0349796 A1. In addition, time of operation (such as start time, end time, or the duration) of the different components of the imager may be recorded.

Optionally, the at least one production unit comprises an exposure unit with a main and/or back exposure means for exposing the relief side and/or the back side of the relief printing precursor. Typically the exposure unit is located downstream of the imager. The at least one parameter may then comprise one or more of the following: main and/or back exposure time, main and/or back exposure power or intensity, number of exposure cycles of main and/or back exposure, a connection quality of the exposure unit, a parameter of a cooler of the exposure unit, a power usage of the exposure unit, a temperature of a part of the exposure unit. In addition, time of operation of the different components of the exposure unit may be recorded.

Optionally, the at least one production unit comprises a washer, and the at least one parameter comprises one or more of the following: the nature of the washing medium (e.g. solvent or water), washing speed, a temperature of a liquid in the washer and/or of the relief plate being washed, a maximal washing temperature during the washing of the relief plate, a minimal washing temperature during the washing of the relief plate, washing duration, viscosity data of a liquid in the washer, a minimal viscosity during the washing of the relief plate, a maximal viscosity during the washing of the relief plate, a viscosity at the start of the washing, a viscosity at the end of the washing, the solid content of the liquid, levels of the liquids in different compartments of the washer, consumption of liquid, time of addition or removal of liquid.

Optionally, the at least one production unit comprises a dryer, and the at least one parameter comprises one or more of the following: drying duration, drying temperature of the relief plates being dried, a minimal temperature during the drying of the relief plate, a maximal temperature during the drying of the relief plate, a temperature at the beginning of the drying, a temperature the end of drying, consumption of a drying medium (e.g. air).

Optionally, the at least one production unit comprises a post-exposure unit downstream of the dryer, and the at least one parameter comprises one or more of the following: post-exposure duration, delay times between different steps performed by the post-exposure unit, a minimal temperature during the post-exposure of the relief plate, the type of light source (e.g. UVA, UVC), duration of exposure, power of exposure, a maximal temperature during the post-exposure of the relief plate, a temperature at the beginning of the post-exposure of the relief plate, a temperature at the end of the post-exposure of the relief plate. In addition, time of operation of the different components of the post-exposure unit may be recorded.

According to a further aspect there is provided a method of operating a relief plate production system comprising at least one, preferably at least two production units for treating a relief plate precursor to obtain a relief plate and a computing means. The method comprises the following steps performed by said computing means: receiving from the at least one production unit information relative to the treatment performed on the relief plate precursor by the respective production unit; analysing the received data to detect a malfunctioning and/or to detect whether an improvement in the relief plate production system is possible; and in the event that a malfunctioning or a possible improvement is detected, informing a user, e.g. by email or any other messaging service, thereof and/or performing predictive maintenance. This method may also be used for multiple plate production systems each having at least one production unit, and may provide in that case even better results.

With these features, after the computing means has analysed the received data, when it notices an anomaly it could alert the user and/or already carry out maintenance based on the analysis, for example based on empirical data on how long a production unit can operate before maintenance is needed. In this manner the relief plate production system can be operated in a more proactive manner by reacting in real time on data from a production unit or even proactively anticipating when the maintenance would be needed. The service life of the relief plate production system is extended. The relief plate production system according to this embodiment is more reliable. In addition, with the alert an operator does not need to monitor the dashboard of the relief plate production system constantly or even on a daily basis. Instead, he will receive an alert when a problem occurs.

Optionally, the receiving comprises receiving parameter data of a production unit in function of time, and the analysing comprises predicting when a component of the production unit needs to be replaced or serviced based on the received data. By anticipating when a component will need to be replaced or serviced the operation of the relief plate production system is more proactive. One does not wait until problems occur to react; instead, the components in the relief plate production system are always kept in a condition for a better performance.

Each of the aspects of the disclosure may comprise any one of, or any technically possible combinations of the following features.

The computing means may be a central computing means or a distributed computing means. The computing means may be part a computing cloud. This embodiment therefore does not require modifications to the existing production units for implementing an advanced data analysis. Also, placing the computing means in a cloud puts a lighter burden on the local computational resources.

The at least one production unit may comprise at least one, preferably two, more preferably at least three, even more preferably at least four of the followings: a transport unit, a pre-processing unit, an imaging unit, an exposure unit, a development unit, such as a washer or a thermal development unit, a post-processing unit, such as a dryer, a post-exposure unit, a post-processing unit such as a cutting unit configured to cut the plate, a mounting unit configured to mount the relief precursor onto a substrate such as a sleeve, a storage unit. Most preferably, the at least one production unit comprises at least an imager, an exposure unit, a development unit. The production units may be grouped in a single machine.

According to a further aspect there is provided a computing means comprising computer-executable instructions configured to carry out the steps of the method of any one of the previous embodiments.

According to a further aspect there is provided a computer program product comprising computer-executable instructions for performing the method of any one of the previous embodiments, when the program is run on a computer.

According to a further aspect there is provided a plate production system comprising at least one production unit for treating a relief plate precursor to obtain a relief plate, and a computing means as defined above.

Any feature of any one aspect of the present disclosure can be combined with any feature of any other aspect(s) of the present disclosure.

### BRIEF DESCRIPTION OF THE DRAWINGS

The above and further aspects of the disclosure will be explained in more detail below on the basis of a number of embodiments, which will be described with reference to the appended drawings. In the drawings:

FIG. 1 is a schematic diagram of an embodiment according to the first aspect of the disclosure;

FIG. 2 is a schematic diagram of according to a further aspect of the disclosure;

FIG. 3 is a schematic diagram illustrating two relief plate production systems according to an embodiment of the disclosure, each relief plate production system comprising an imager, an exposure unit, a washer, and a dryer;

FIG. 4 is a schematic diagram of an embodiment according to a further aspect of the disclosure.

### DESCRIPTION OF EXEMPLARY EMBODIMENTS

Flexographic printing or letterpress printing are techniques which are commonly used for high volume printing. Flexographic or letterpress printing plate are relief plates with printing elements, typically called reliefs or dots, protruding above non-printing elements in order to generate an image on a recording medium such as paper, cardboard, films, foils, laminates, etc. Also, cylindrically shaped printing plates or sleeves may be used.

Various methods exist for making flexographic printing plate precursors. According to conventional methods, flexographic printing plate precursors are made from multilayer substrates comprising a backing layer and one or more photocurable layers (also called photosensitive layers). Those photocurable layers are imaged by exposure to electromagnetic radiation through a mask layer containing the image information or by direct and selective exposure to light e.g. by scanning of the plate to transfer the image information in order to obtain a relief plate.

The relief precursor is for example a digital relief precursor or an analogue relief precursor. In case of a digital relief precursor the mask layer is an integral layer of the precursor, and the imaging of the mask layer results in an ablated layer, whereas in case of an analogue relief precursor the mask layer is typically a separate layer, such as a film, which comprises areas which are transparent for radiation and areas which are not transparent for radiation, and which is mounted onto the relief precursor prior to exposure with electromagnetic radiation. For example, a non-transparent ablatable layer on a substrate layer may be used and the structures may be generated by ablation, or the transmission of a layer of a film may be changed by exposure with a laser.

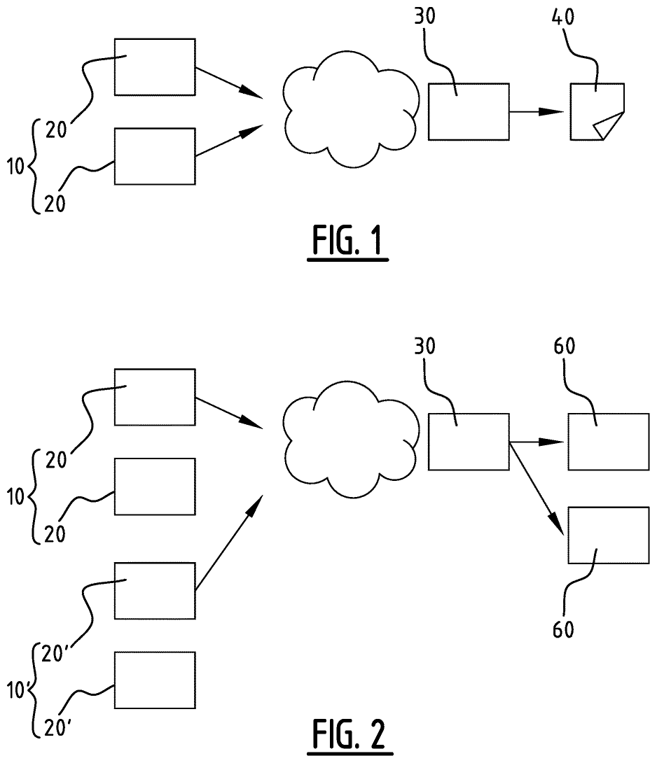

FIG. 1 shows an embodiment according to the first aspect of the disclosure. According to the first aspect of the disclosure is a method of analysing data from a relief plate production system 10. The relief plate production system 10 comprises at least one, preferably at least two production units 20 for treating a relief plate precursor and obtaining a relief plate. The at least one production unit may comprise at least e.g., an exposure unit and a development unit. Optionally, also an imager may be present, or the relief plate precursors may be imaged or provided with a mask elsewhere. The relief plate production system 10 also comprises a computing means 30.

Wherever this text mentions at least one production unit, it also discloses the possibility of having at least two production units.

The at least one production unit 20 can comprise at least two of the following: an imager, an exposure unit, a washer, a dryer, as shown in FIG. 3. More generally the at least one production unit 20 can comprise at least two of the followings: a transport unit, a pre-processing unit, an imaging unit, an exposure unit, a development unit, such as a washer or a thermal development unit, a post-processing unit, such as a dryer, a post-exposure unit, a post-processing unit such as a cutting unit configured to cut the plate, a mounting unit configured to mount the relief precursor onto a substrate such as a sleeve, a storage unit. It is noted that a plate production system may also comprise multiple exposure units (same or different) or multiple developments units (e.g. a washer and a thermal development unit) or more generally multiple units mentioned above operating in parallel.

The computing means 30 is configured to perform the steps of: receiving from the at least one production unit 20 data comprising a plate identifier of the relief plate and information relative to the treatment performed on the relief plate precursor by the respective production unit 20; and analysing the received data and creating a relief plate report 40 based on the analysed data.

The computing means 30 is preferably distinct from the at least one production unit 20. According to one embodiment the computing means is located in a server. According to one embodiment the computing means 30 is located in a computing cloud. According to some embodiments all the production units 20 of a plate production system 10 are configured to send information to the computing means 30. According to some embodiments the relief plate report is generated using information received from all the production units 20 of the relief plate production system 10.

According to one embodiment the computing means 30 is capable of sending the relief plate report 40 to an external terminal, such as to a mobile computer device or a fixed computer device. A user then can read the relief plate report 40 on the external terminal.

The computing means 30 receives data from the at least one production unit 20. The computing means 30 receives the data via a wire or wirelessly. The data comprises a plate identifier of the relief plate. The data also comprises information relative to the treatment performed on the relief plate by the respective production unit 20.

The identifier is for example attached or integrated to the relief plate precursor. Alternatively, the identifier is attached or integrated to a carrier, such as a trolley, carrying the relief plate precursor. The carrier is for example linked to the at least one production unit wirelessly. Alternatively the trolley may have a plurality of screws each able to occupy at least two positions. Through the combination of the screws' positions information on the precursor type on the trolley can be obtained. For example, there are three screws on the trolley and each screw has two positions. In this setup the screws can have eight possible combinations in total which can represent eight plate types. According to some embodiments the trolley can be identified for example by an RFID tag.

According to various aspects of the disclosure the indication of the identifier is generated in the relief plate precursor by the imager. According to some embodiments the identifier is already visible to human eyes even before the relief precursor is exposed by an exposure unit.

A production unit may receive a job instruction and treat the plate in accordance with the job instruction. The job instruction may also comprise the identifier of the relief precursor, typically a unique identifier. Each job instruction may have its own unique identifier distinct from that of any other job instruction. That unique identifier is according to some embodiments a universally unique identifier (UUID). The UUID may be created using specific software for example Win32 API function UuidCreate that is provided by Microsoft as a part of the Windows API. The job instruction may also comprise at least one look-up parameter configured to allow a production unit to determine the configuration settings to be used to treat the relief plate precursor. The look-up parameter may comprise information on the type of the relief plate precursor. Alternatively or in addition, the look-up parameter may comprise information on the size of the relief precursor. Alternatively or in addition, the look-up parameter may comprise information on the thickness of the relief precursor. Alternatively or in addition, the look-up parameter may comprise information on different treatment options on the same type of relief precursor. For example, for one type of the relief precursor it may be desirable that the plate can be treated under different parameters to suit different customer needs. For example, for the plate type A with a customer requirement C1, the job instruction comprises a first series of look-up parameters which enable the production unit to treat the relief precursor with the setting 1. For the plate type A with a customer requirements C2, the job instruction comprises a second series of look-up parameters which enable the production unit to treat the relief precursor with the setting 1′. For a plate type B with a customer requirement C1, the job instruction comprises a third series of look-up parameters which enable a production unit to treat the relief precursor with the setting 2.

According to some embodiments the relief plate report 40 comprises information on the relief plate treated by at least one production unit 20. According to some embodiments the relief plate report 40 comprises aggregated information on a relief plate based on data received from at least two of the production units 20. According to some embodiments the relief plate report 40 comprises aggregated information on a relief plate based on data received from all the production units 20 involved in the manufacturing of the relief plate.

The relief plate report 40 may comprise any one or more of the following: the plate identifier of the relief plate, dimensions of the relief plate, such as a length, width and thickness of the relief plate, identifiers of the at least one production unit that has treated the relief plate precursor, settings used in the at least one production unit, a waste percentage indicating an area of a relief plate not taken up by image files compared to the total area of the relief plate, a job identifier identifying a job performed on the relief plate precursor by the at least one production unit, image data associated with the treatment by the at least one production unit, measurement data measured during or after the treatment by the at least one production unit, such as a floor thickness, a warning if an anomaly is detected in the analysed data.

The image data associated with the treatment by the at least one production unit is for example contained in a tiff file. Such image data may be sent separately to a production unit, and in particular to the imager. The image data included in the relief plate report may be a low-resolution version of the original image data used for the imaging.

Some of the measured parameters are for example measured by a production unit. In addition or alternatively some of the measured parameters are measured by a machine distinct from any production unit 20 in the relief plate production system 10. According to some embodiments the received data comprises measurement data based on measurements performed by the at least one production unit 20 and/or based on a measurement performed in a separate unit downstream of the at least one production unit 20. The measurement data for example comprises data about a measurement performed on a treated relief plate, such as the plate thickness, and/or the thickness of a floor of the treated relief plate, and/or the lowest stable tonal value that can be produced on the relief plate, and/or a dot gain. In addition or alternatively the measurement data comprises production unit related data and/or data related to the environment around a production unit 20, such as temperature data for example of the relief plate and/or of the treated relief plate and/or of at least one production unit 20. In addition or alternatively the measurement data comprises data based on results of printing with the treated plate.

When the at least one production unit 20 comprises an imager 21, the relief plate report 40 may comprise one or more of the parameters mentioned in the summary for the imager. When the at least one production unit 20 comprises an exposure unit 22, the relief plate report 40 may comprise one or more of the parameters mentioned in the description of the exposure unit. Similarly, when the at least one production unit 20 comprises a washer 23, the relief plate report 40 may comprise one or more of the parameters mentioned in the description of the washer. Similarly, when the at least one production unit 20 comprises a dryer 24, the relief plate report 40 may comprise one or more of the parameters mentioned in the description of the dryer. Similarly, when the at least one production unit 20 comprises a post-exposure unit, the relief plate report 40 may comprise one or more of the parameters mentioned in the description of the post-exposure unit.

According to some embodiments the method further comprises the step of analysing the relief plate report 40 when a parameter of the treated relief plate or a process parameter does not fall within its expected range. In addition or alternatively the method further comprises the step of analysing the relief plate report 40 when a printing result of the treated relief plate does not fall within its expected printing quality. In this case, the result of the analysis can distinguish any problems coming from the treated relief plate itself before printing, i.e. before any ink is applied to the treated relief plate, from issues due to the printing process using the treated relief plate, i.e. after ink is applied to the treated relief plate, which ink is transferred to the printing medium. In this manner one could identify the source of the problem: the treated relief plate itself or a subsequent inking and printing step.

According to some embodiments the method further comprises, in a production unit, the step of reading or receiving the plate identifier of a relief plate precursor that is to be treated, and sending the plate identifier together with the information relative to the treatment performed to the computing means.

Optionally, the method further comprises the step of attaching or including the relief plate report 40 or an identifier of the relief plate report 40 to/with the obtained relief plate. For example, a code, such as a barcode or a QR code can be integrated in the relief plate or attached to the relief plate. This may be the same code as the one used for the plate identifier or a different code. By scanning the code an operator can obtain the relief plate report 40.

According to some embodiments the relief plate report 40 contains information on the temporal evolution of data. According to one embodiment the relief plate report 40 is created after the relief plate is treated by the relief plate production system 10, i.e. after the relief plate is treated by all the production units 20 in the relief plate production system 10.

According to some embodiments the method comprises creating at least two relief plate reports 40 based on the same received data. These relief plate reports 40 comprise an extended relief plate report and a limited relief plate report. The extended relief plate report contains more information than the limited relief plates report. The extended relief plate report is for example intended for the relief plate producer. The limited relief plate support is for example intended for a customer of the relief plate producer. The extended relief plate support may contain information that the relief plate producer considers confidential (for example information from other customers) and does not want to show to a certain customer. This confidential information is not included in the limited relief plate report.

According to some embodiments the relief plate report 40 contains a quality certificate of the relief plate.

According to some embodiments the relief plate report 40 contains a timestamp indicating when the relief plate report 40 is generated. According to some embodiments the relief plate report 40 contains timestamps each indicating when a production unit 20 has finished treating the relief plate. For example, the relief plate report 40 contains a first timestamp indicating when the imager 21 finished imaging the relief plate and a second timestamp indicating when the exposure unit 22 finished exposing the relief plate.

According to some embodiments the method comprises providing a status report of the relief plate production system. The status report gives an overview of the production status of the relief plate production system and is generated by the computing means based on the received and analysed data over a period of time. The status report is for example provided periodically, such as on a daily, weekly, or monthly basis. The status report is for example sent to an operator periodically, such as sent out via an email. In this way, compared to providing information on a display of the relief plate production system, an operator receives automatically an overview of the status of the relief plate production system.

According to some embodiments the relief plate production system 10 is able to communicate with another system, for example with an Enterprise Resource Planning system. The Enterprise Resource Planning system can thus have an overview of the relief plate production system.

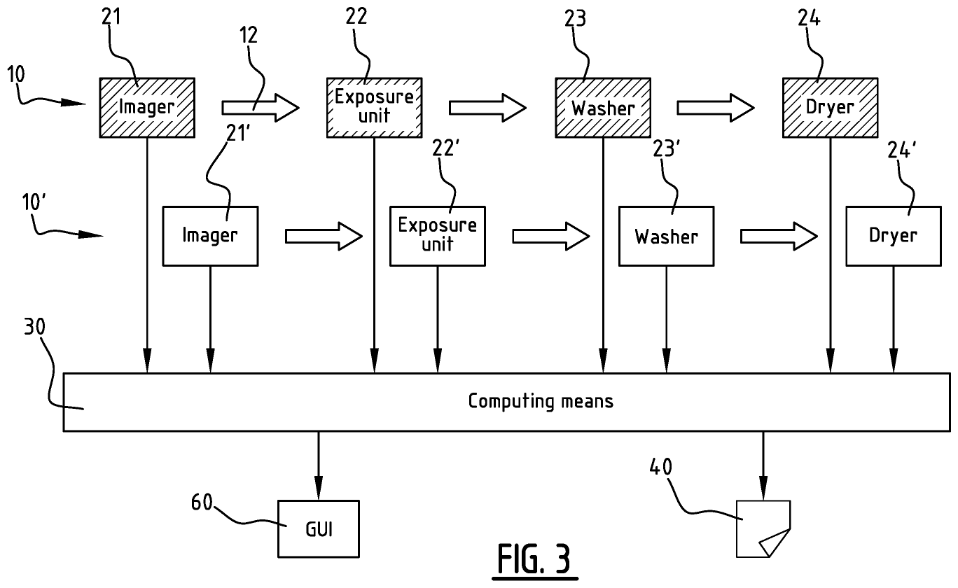

FIG. 2 shows an embodiment according to a further aspect of the disclosure. According to the further aspect there is provided a method of analysing data from one or more relief plate production systems 10, 10′. Each relief plate production system 10, 10′ comprises at least one, preferably at least two production units 20, 20′ for treating a relief plate. The relief plate production system(s) 10, 10′ also has/have a computing means 30. According to a preferred embodiment some of or all the relief plate production systems 10, 10′ share a computing means 30.

The method comprises at said computing means 30 the step of receiving from each production unit 20, 20′ of the one or more plate production systems 10, 10′ data related to the treatment performed by the respective production unit. The method further comprises analysing the received data and based thereon showing data in a graphical user interface 60 for a respective plate production system 10, 10′, wherein said graphical user interface 60 is shows at least one of the following:
a graphical representation of at least one parameter associated with the respective plate production system 10, 10′ in function of time;
a graphical representation of at least one parameter associated with the respective plate production system 10, 10′ in function of a resolution of an imaging file used the plate production system;
a graphical representation indicating for each of the at least one production unit 20, 20′ at least one parameter of the respective plate production system 10, 10′;
information allowing a comparison of the respective plate production system 10 with other plate production systems 10′ of said one or more plate production systems;
a geographical map indicating the one or more plate production system together with one or more parameters associated with said one or more plate production systems.

There may be provided a separate graphical user interface 60 for each plate production system 10, 10′ or a common user interface 60 showing data for multiple plate production systems 10.

According to some embodiments the graphical user interface 60 is configured to show a graphical representation about the respective plate production system 10, 10′ in function of time, e.g. any one of the parameters mentioned in the summary. This possibility enables an operator to see any variation over time during the manufacturing of multiple relief plates. He can then observe any trend in this variation. He can for example distinguish the case where the floor of the relief plates becomes thicker and deviates from the acceptable range, which implies issues to be looked into, from a simple fluctuation of the thickness of the floor within the acceptable range, which is allowable.

In addition or alternatively, the graphical user interface 60 may be configured to show a graphical representation about the respective plate production system 10, 10′ in function of resolution. The resolution here may be the resolution of the image file or the resolution of the printing features of the relief plate. In addition or alternatively, the graphical user interface 60 is configured to show a map indicating the at least one production unit 20, 20′ associated with information about the respective plate production system 10, 10′. In addition or alternatively, the graphical user interface 60 is configured to show information about the respective plate production system 10, 10′ as well as information allowing a comparison of the respective plate production system 10 with other plate production systems 10′ of said one or more plate production systems.

According to some embodiments one relief plate production system 10 belongs to one customer and another relief plate production system 10′ belongs to another customer. It is therefore possible to compare the data from one customer with the data from another customer.

According to some embodiments with the map indicating the at least one production unit 20, 20′ associated with information about the respective plate production system 10, 10′ it is also possible to compare the relief plate production systems 10, 10′ located in two different locations. It is for example possible to identify any differences due to differences in locations. For example, when a relief plate production system based in North America has a 20% waste rate whereas the relief plate production systems in other parts of the world only on average have a 15% waste rate, the manufacturer of the relief printing plates can inform the customer in North America that there is room for improvement. According to some embodiments the maps show the production volume of different types of printing plates through the relative size of circles on the graphical user interface 60.

All graphs and information shown on the graphical user interface 60 may be stored or printed for documentation reasons.

According to some embodiments each plate production system 10, 10′ comprises a production unit of a first type. The production unit of the first type is for example an imager 21, 21′, or an exposure unit 22, 22′, or a washer 23′, 23′, or a dryer 24, 24′. Under these embodiments the method further comprises determining based on the received data which features of the production unit of the first type are used for each plate production system 10, 10′. For example, when the production unit of the first type is an imager, the features may be which sampling pattern is imposed on the image file controlling the ablation of the mask layer. For example, when the production unit of the first type is an exposure unit 22, 22′ the features may be which level of illumination intensity is used to expose the photopolymerisable layer. Preferably the method also comprises ranking used features based on the number of times that a feature has been used.

According to some embodiments the graphical user interface 60 comprises at least one of the followings: the total number of the relief plates processed by a production unit, a number of the relief plates processed by a production unit in function of time, a waste percentage indicating the area of a relief plate not taken up by image files compared to the total area of the relief plate in function of time, a process parameter of a production unit in function of time. In addition or alternatively, the graphical user interface 60 comprises at least one of the following: the total surface area of the relief plates processed by a production unit, an average time for a product unit to process a relief plate, the on-time of the production unit, the integrity of the production unit (for example, whether hardware such as the illumination source is still performing as it should; as another example, when the last hardware check was carried out), the status of the production unit (for instance the status of the production unit indicates that the machine is in at least one of the following states: idle, producing, initializing, shutting down, error state, integrity check, in the course of moving a plate from one production unit to another). According to some embodiments the graphical user interface 60 comprises at least one of the following: the motor speed of one production unit (for example, the motor of the pump of the washer, or of the lead screw, or of the drum of the imager), a tolerance parameter, the fluid level in the washer, the viscosity of the solvent in the washer, the illumination intensity of the exposure unit, the error condition of the production unit, the warning level of a production unit, the power usage of one production unit.

According to some embodiments the graphical user interface 60 indicates the types of relief plates treated by at least one production unit 20. According to some embodiments the graphical user interface 60 comprises the proportion of time that each relief plate spends in a production unit 20 with regard to the total time that this relief plate spends in the relief plate production system 10, 10′. For example, the graphical user interface 60 can show that a relief plate spent 20% of its time in the relief plate production system 10, 10′ in the imager 21, 21′, 30% of its time in the relief plate production system 10, 10′ in the exposure unit, 20% of its time in the relief plate production system 10, 10′ in the washer 23, 23′, and 30% of its time in the relief plate production system 10, 10′ in the dryer 24, 24′.

According to some embodiments the graphical user interface 60 indicates the surface area of the relief plates treated by one production unit 20, 20′ or by the relief plate production system 10, 10′ in function of time, such as in function of days. According to some embodiments the graphical user interface 60 indicates the number of the relief plates treated by one production unit 20, 20′ or by the relief plate production system 10, 10′ in function of time, such as in function of days. According to some embodiments the graphical user interface 60 indicates the relief plate thickness in function of time. According to some embodiments the graphical user interface 60 indicates at least one of the parameters mentioned in this application about the relief plate production system 10, 10′ or about at least one production unit 20, 20′ in function of time.

According to some embodiments the at least one production unit 20, 20′ comprises an imager 21, 21′, and the graphical user interface 60 shows one or more of the following: a parameter of the imager, a status of the imager, at least part of input from an operator, number of laser beams, size of laser beams, ablation power of the imager, a ratio of the ablation power actually used by the imager for imaging the relief plate compared to the maximum ablation power available on the imager, a measured rotation speed of a drum in the imager with the relief plate being fixed on the drum, a connection quality of the imager, a temperature of the imager and/or of the relief plate, an ablation resolution, power consumed to treat the relief precursor, an imaging duration, a start time of imaging, an end time of imaging. Optionally the imager may comprise means to investigate the quality of the obtained mask e.g. by determination of the optical density or other optical methods, such as those described in DE 20 2022 002301 U1 and US 2022/0349796 A1. In addition, time of operation of the different components of the imager may be shown.

According to some embodiments the at least one production unit 20, 20′ comprises an exposure unit 22, 22′, and the graphical user interface 60 comprises one or more of the following: main and/or back exposure time, main and/or back exposure power, number of exposure cycles, a parameter of the exposure unit, at least part of the input from an operator, a connection quality of the exposure unit, a parameter of a cooler of the exposure unit, a power usage of the exposure unit, a temperature of at least a part of the exposure unit. In addition, time of operation of the different components of the exposure unit may be shown.

According to some embodiments the at least one production unit 20, 20′ comprises a washer 23, 23′, and the graphical user interface 60 shows one or more of the following, e.g. in function of time: nature of the washing medium (e.g. solvent or water), washing speed, a temperature of a solvent in the washer and/or of the relief plate being washed, the maximal washing temperature during the washing of the relief plate, the minimal washing temperature during the washing of the relief plate, washing duration, viscosity data of a solvent in the washer, the minimal viscosity during the washing of a relief plate, the maximal viscosity during the washing of a relief plate, the viscosity at the start of the washing, the viscosity at the end of the washing, a parameter of the washer, solid content of the liquid (for example the maximal or minimal solid content during the washing of a relief plate), levels of the liquids in different compartments of the washer, consumption of liquid, time of addition or removal of liquid, at least part of the input from an operator. According to some embodiments the graphical user interface 60 may indicate the volume of the solvent or water in the washer. According to some embodiments the graphical user interface 60 may comprise the length during which the washer is off (for example 30 minutes). According to some embodiments the graphical user interface 60 indicates the duration when there is an error in the washer.

According to some embodiments the graphical user interface 60 indicates the surface area of the relief plates treated by the washer in function of time. According to some embodiments the graphical user interface 60 shows information on a pre-washer before the relief plate is treated by the washer. Information on the pre-washer for example comprises the volume of the solvent in the pre-washer, and/or the temperature of the solvent in the pre-washer.

According to some embodiments the at least one production unit 20, 20′ comprises a dryer 24, 24′, and the graphical user interface 60 indicates one or more of the following: drying duration, drying temperature of the relief plates, the minimal temperature during the drying of the relief plate, the maximal temperature during the drying of the relief plate, the temperature at the beginning of the drying, the temperature the end of drying, the consumption of a drying medium (e.g. air), a parameter of the dryer, at least part of the input from an operator. According to some embodiments the graphical user interface 60 shows aggregated information on at least two dryers. In this way comparisons between different dryers could be made.

According to some embodiments the at least one production unit 20, 20′ comprises a post-exposure unit downstream of the dryer 24, 24′, and the graphical user interface 60 shows one or more of the following: type of light source (e.g. UVA, UVC), duration of exposure, power of exposure, post-exposure duration, delay times between different steps performed by the post-exposure unit (for example, a delay is imposed before a first type of illumination is started in the exposure unit), the minimal temperature during the post-exposure of a relief plate, the maximal temperature during the post-exposure of a relief plate, the temperature at the beginning of the post-exposure of a relief plate, the temperature at the end of the post-exposure of a relief plate. According to some embodiments the graphical user interface 60 shows the temperature of the post-exposure unit in function of time. In addition, time of operation of the different components of the post-exposure unit may be shown.

According to some embodiments the graphical user interface 60 shows the distribution of the treatment statuses of relief plates across a period of time. For example, the production graphic user interface 60 shows that in the course of a day 90% of the relief plate treatments by a production unit 20, 20′ or by the relief plate production system 10 are finished, and 10% of relief plate treatments by the production unit 20, 20′ or by the relief plate production system 10 are cancelled. The period of time may be selected by an operator, for example today, last week, last year, last February, or from 6th June 10 AM to 10th June 2 PM.

According to some embodiments the graphical user interface 60 indicates the health of at least one production unit 20, 20′. The production unit health for instance indicates the hardware health, for example the hardware health of the exposure unit. In this example the hardware health can for example indicate whether the illumination sources are still working, and/or whether the output illumination intensity is high enough.

According to some embodiments the graphical user interface is configured to apply a filter to a graph shown in the graphical user interface 60. For example, the filter can be applied to show only the relief plates from one relief plate manufacturer in the graphical user interface 60.

According to some embodiments it the graphical user interface is configured to zoom in on a graphical representation to study more closely the shown results, e.g. to study more closely the evolution of a graph in a shorter period time. According to some embodiments the graphical user interface 60 is configured to adjust the scale of the other graphs according to a scale used of one graph. For instance, when the user zooms in on the temperature of the washer, the graph on the viscosity of the solvent is zoomed in accordingly, as increasing the temperature also has an impact on the viscosity of the solvent in the washer.

According to some embodiments the relief plate production system 10 is configured to allow a user to input information, such as a free format command, via an input interface. The relief plate production system 10, and in particular the computing means 30 may be configured to receive the information input by the user and to take it into account for presenting information in the relief plate report 40 and/or on the graphical user interface 60 and/or in the status report of the relief plate production system. In one example, the information is input through the graphical user interface 60 or through another user interface, for example a user interface of a mobile device of the user. For example, the information may be sent by a user to the computing means 30. In addition or alternatively, the information is input to the relief plate production system 10 via a file, such as a . txt file. The input information may contain any information that can have an influence on the quality of the produced relief plate, and/or is worthy of being included in the relief plate report 40 and/or on the graphical user interface 60 and/or in the status report of the relief plate production system. The information may be for instance information related to the printing result obtained with this produced relief plate, information related to environmental conditions during the production (e.g. environment temperature), information relating to a malfunctioning component of a production unit, measurement data performed on the plate by a user using a measurement tool, etc.

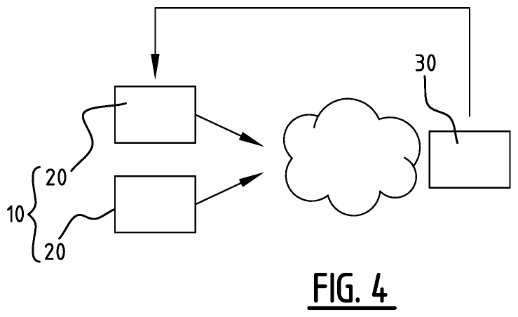

FIG. 4 shows an embodiment according to a further aspect of the disclosure. According to this aspect there is provided a method of operating a relief plate production system 10 comprising at least one, preferably at least two production units 20 for treating a relief plate and a computing means 30. The method comprises at said computing means the step of receiving from the at least one production unit 20 data related to the operation of the respective production unit 20, 20′. The method also comprises at said computing means 30 the step of analysing the received data. The method also comprises at said computing means 30 the step of informing/alerting the user and/or performing predictive maintenance based on the analysed data.

The alert is for example sent when an anomaly is detected. The alert may comprise any one or more of the following situations: a cooler broke down; at least one illumination source, for example a light-emitting diode was not functioning properly; the temperature of the relief printing plate was above a predetermined threshold.

The alert is for example sent to the user in an email. In addition or alternatively the alert may be sent to the smartphone of the user.

The predictive maintenance here may be carried out on the relief plate production system 10 which sends data to the computing means 30 for analysis. In addition or alternatively the predictive maintenance may be carried out on a relief plate production system which did not send data to the computing means 30 for analysis. In the latter situation, when one production unit 20 has problems, other production units of the same or similar specification in another relief place production system 10 may also have problems now or could have problems very soon. By carrying out the predictive maintenance malfunctioning in other similar production units can be prevented. According to some embodiments the receiving comprises receiving parameter data in function of time. The analysing comprises predicting when a component of a production unit 20 needs to be replaced or serviced based on the received data.

Any feature of any one aspect of the present disclosure can be combined with any feature of any other aspect(s) of the present disclosure.

1. A method of analysing data from a relief plate production system comprising at least one, preferably at least two production units for treating a relief plate precursor to obtain a relief plate, and a computing means the method comprising at said computing means the steps of:
receiving from the at least one production unit data comprising a plate identifier of the relief plate and information relative to the treatment performed on the relief plate precursor by the respective production unit; and
analysing the received data and creating a relief plate report based on the analysed data.

2. The method according to claim 1, wherein the relief plate report comprises aggregated information on the treated relief plate precursor based on the information received from the at least one production unit.

3. The method according to claim 1, wherein the relief plate report comprises any one or more of the following: the plate identifier of the relief plate, dimensions of the relief plate, such as a length, width and thickness of the relief plate, identifiers of the at least one production unit that have treated the relief plate precursor, settings used in the at least one production unit, a waste percentage indicating an area of a relief plate not taken up by image files compared to the total area of the relief plate, a job identifier identifying a job performed on the relief plate precursor by the at least one production unit, image data associated with the treatment by the at least one production unit, measurement data measured during or after the treatment by the at least one production unit, such as a floor thickness, a warning if an anomaly is detected in the analysed data.

4. The method according to claim 1, wherein the received data comprises measurement data based on measurements performed by the at least one production unit and/or the method further comprises receiving measurement data from a separate unit downstream of the at least one production unit.

5. The method according to claim 3, wherein the measurement data comprises data about a physical property of a treated relief plate, such as a plate thickness, and/or a thickness of a floor of the treated relief plate precursor, and/or measurement data based on measured printing results such as a lowest stable tonal value produced on the relief plate, and/or a dot gain.

6. The method according to claim 3, wherein the measurement data comprises production unit related data and/or data related to the environment around a production unit, such as a temperature of the relief plate precursor before and/or during and/or after the treatment and/or a temperature inside at least one of the at least one production unit; and/or wherein the measurement data comprises data based on results of printing with the treated plate, optionally further including printing related data such as type of ink, type of printing medium.

7. (canceled)

8. The method according to claim 1, wherein the at least one production unit comprises an imager with an imaging means, such as a laser, and the relief plate report comprises one or more of the following: an imaging duration, imaging power, imaging speed, positions of the imaging means, measured parameters of an actuator such as a motor used for moving the imaging means relative to the relief plate precursor, such as motor current, motor speed, a time interval used for generating an imaged feature corresponding with an imaging pixel, e.g. an on-time value for controlling a beam of the imaging means, a beam diameter value and/or beam shape value for controlling a beam of the imaging means, a number of passes performed by the imaging means, an indication of which one or more imaging heads of the imaging means have been used, temperature inside the imager.

9. The method according to claim 1, wherein the at least one production unit comprises an exposure unit with a main and/or back exposure means for exposing a relief side and a back side of the relief plate precursor, and the relief plate report comprises one or more of the following: main and/or back exposure time, main and/or back exposure power and/or dose, number of exposure cycles performed by the main and/or back exposure means, a speed at which the main and/or back exposure means is moved relative to the relief plate precursor, temperature of the relief plate precursor and/or a temperature in the exposure unit, data related to cooling of the exposure unit, power consumed by the exposure unit.

10. The method according to claim 1, wherein the at least one production unit comprises a washer, and the relief plate report comprises one or more of the following: washing speed, washing temperature, washing duration, viscosity data of a liquid in the washer, power consumed by the washer.

11. The method according to claim 1, wherein the at least one production unit comprises a dryer, and the relief plate report comprises one or more of the following: drying temperature, drying duration, consumption of a drying medium, power consumed by the dryer.

12. The method according to claim 1, further comprising the step of analysing the relief plate report when a parameter of the relief plate or a printing result of the relief plate does not fall within its expected range or printing quality and determining a cause thereof.

13. The method according to claim 1, further comprising, in a production unit, the step of reading or receiving the plate identifier of a relief plate precursor that is to be treated, and sending the plate identifier together with the information relative to the treatment performed to the computing means; and/or an further comprising the step of attaching or including the relief plate report or an identifier of the relief plate report to/with the treated relief plate.

14. (canceled)

15. A method of analysing data from one or more relief plate production systems each comprising at least one, preferably at least two production units for treating a relief plate precursor and obtaining a relief plate and a computing means, the method comprising at said computing means the steps of:
receiving from each production unit of the one or more plate production systems data related to the treatment performed by the respective production unit; and
analysing the received data and based thereon showing data in a graphical user interface for a respective plate production system, wherein said graphical user interface is configured to show at least one of the following:
a graphical representation of at least one parameter associated with the respective plate production system in function of time;
a graphical representation of at least one parameter associated with the respective plate production system in function of a resolution of an imaging file used the plate production system;
a graphical representation indicating for each of the at least one production unit at least one parameter of the respective plate production system
a graphical representation of at least one parameter associated with power consumption of at least one production unit;
a graphical representation of at least one parameter associated with solvent consumption of at least one production unit;
information allowing a comparison of the respective plate production system with other plate production systems of said one or more plate production systems;
a geographical map indicating the one or more plate production system together with one or more parameters associated with said one or more plate production systems.

16. The method according to claim 15, wherein each plate production system comprises a production unit of a first type, and wherein the method further comprises determining based on the received data which features of the production unit of the first type are used for each plate production system and optionally ranking used features based on a number of times a feature has been used.

17. The method according to claim 15, wherein the at least one parameter comprises at least one of the followings: a number of the relief plates treated by a production unit, a surface area treated by a production unit, a waste percentage indicating the area of a relief plate not taken up by image files compared to the total area of the relief plate, a process parameter of a production unit, an integrity parameter of a production unit, power consumption of a production unit, a status of a production unit.

18. The method according to claim 15, wherein the at least one production unit comprises an imager, and the at least one parameter comprises one or more of the following: a status of the imager, power consumed by the imager, maximum ablation power of the imager, a ratio of ablation power actually used by the imager for imaging the relief plate compared to the maximum ablation power available on the imager, a measured rotation speed of a drum in the imager with the relief plate precursor being fixed on the drum, a connection quality of the imager, a temperature of the imager and/or of the relief plate precursor, an imaging resolution, an imaging duration, a start time of imaging, an end time of imaging, power consumed by the imager.

19. The method according to claim 15, wherein the at least one production unit comprises an exposure unit, and the at least one parameter comprises one or more of the following: main and/or back exposure time, main and/or back exposure power or intensity, number of exposure cycles of main and/or back exposure, a connection quality of the exposure unit, a parameter of a cooler of the exposure unit, a power usage of the exposure unit, a temperature of a part of the exposure unit, power consumed by the exposure unit.

20. The method according to claim 15, wherein the at least one production unit comprises a washer, and the at least one parameter comprises one or more of the following: washing speed, a temperature of a liquid in the washer and/or of the relief plate being washed, a maximal washing temperature during the washing of the relief plate, a minimal washing temperature during the washing of the relief plate, washing duration, viscosity data of a liquid in the washer, a minimal viscosity during the washing of the relief plate, a maximal viscosity during the washing of the relief plate, a viscosity at the start of the washing, a viscosity at the end of the washing, power consumed by the washer; and/or wherein the at least one production unit comprises a dryer, and the at least one parameter comprises one or more of the following: drying duration, drying temperature of the relief plates being dried, a minimal temperature during the drying of the relief plate, a maximal temperature during the drying of the relief plate, a temperature at the beginning of the drying, a temperature the end of drying, power consumed by the dryer; and/or wherein the at least one production unit comprises a post-exposure unit downstream of the dryer, and the at least one parameter comprises one or more of the following: post-exposure duration, delay times between different steps performed by the post-exposure unit, a minimal temperature during the post-exposure of the relief plate, a maximal temperature during the post-exposure of the relief plate, a temperature at the beginning of the post-exposure of the relief plate, a temperature at the end of the post-exposure of the relief plate, power consumed by the post-exposure unit.

21. (canceled)

22. (canceled)

23. A method of operating a relief plate production system comprising at least one, preferably at least two production units for treating a relief plate precursor to obtain a relief plate and a computing means, the method comprising at said computing means the steps of:
receiving from the at least one production unit information relative to the treatment performed on the relief plate precursor by the respective production unit;
analysing the received data to detect a malfunctioning and/or to detect whether an improvement in the relief plate production system is possible; and
in the event that a malfunctioning or a possible improvement is detected, informing a user thereof and/or performing predictive maintenance.

24. The method according to claim 23, wherein the receiving comprises receiving parameter data of a production unit in function of time, and the analysing comprises predicting when a component of the production unit needs to be replaced or serviced based on the received data.

25. (canceled)

26. The method according to claim 1, wherein the at least one production unit comprises at least two of the followings: a transport unit, a pre-processing unit, an imaging unit, an exposure unit, a development unit, such as a washer or a thermal development unit, a post-processing unit, such as a dryer, a post-exposure unit, such as a cutting unit configured to cut the plate, a mounting unit configured to mount the relief precursor onto a substrate such as a sleeve, a storage unit.

27. (canceled)

28. A computer program product comprising computer-executable instructions for performing the method of claim 1, when the program is run on a computer.

29. (canceled)
